(19) United States
(12) Patent Application Publication
(10) Pub. No.: US 2012/0135576 A1
(43) Pub. Date: May 31, 2012

(54) METHOD OF FABRICATING SEMICONDUCTOR DEVICE

(76) Inventors: Hyun-Jung Lee, Suwon-si (KR); Young-Pil Kim, Hwaseong-si (KR); Jin-Bum Kim, Seoul (KR); Sang-Bom Kang, Seoul (KR); Kwan-Yong Lim, Seongnam-si (KR)

(21) Appl. No.: 13/242,784

(22) Filed: Sep. 23, 2011

(30) Foreign Application Priority Data
Nov. 30, 2010 (KR) 10-2010-0120504

(51) Int. Cl. H01L 21/336

(52) U.S. Cl. 438/299; 257/E21.409

(57) ABSTRACT

Provided are a semiconductor device and a method of fabricating a semiconductor device. The method includes providing a substrate having a channel region; forming a gate structure, which comprises a dummy gate pattern, on the substrate; forming first and second trenches by recessing the substrate on both sides of the gate structure, respectively; forming a first semiconductor pattern in the first and second trenches; removing the dummy gate pattern to expose a portion of the channel region; forming a recessed channel region by recessing the portion of the channel region; and forming a second semiconductor pattern in the recessed region.

This application claims priority from Korean Patent Application No. 10-2010-0120504 filed on Nov. 30, 2010 in the Korean Intellectual Property Office, the disclosure of which is incorporated herein by reference in its entirety.

### BACKGROUND

1. Field of the Disclosure

The present disclosure relates to a method of fabricating a semiconductor device.

2. Description of the Related Art

For the last decades, semiconductor technology scaling has produced a lot of results and economic effects. For example, a reduction in the design rule of a metal-oxide-semiconductor field-effect transistor (MOSFET) has resulted in a reduction in channel length and a corresponding increase in switching speed. This is because a shorter channel leads to a higher switching speed. As technology improves, even higher switching speeds continue to be desirable.

### SUMMARY

Aspects of the present embodiments provide a method of fabricating a semiconductor device with increased mobility of carriers.

However, aspects of the present disclosure are not restricted to the one set forth herein. The above and other aspects of the disclosed embodiments will become more apparent to one of ordinary skill in the art to which the present disclosure pertains by referencing the detailed description given below.

According to one embodiment, a method of fabricating a semiconductor device is disclosed. The method includes providing a substrate having a channel region; forming a gate structure, which comprises a dummy gate pattern, on the substrate; forming first and second trenches by recessing the substrate on both sides of the gate structure, respectively; forming a first semiconductor pattern in the first and second trenches; removing the dummy gate pattern to expose a portion of the channel region; forming a recessed channel region by recessing the portion of the channel region; and forming a second semiconductor pattern in the recessed region.

In a further embodiment, a further method of fabricating a semiconductor device is disclosed. The method includes providing a substrate having a channel region; forming a gate structure, which comprises a dummy gate pattern and a gate insulating layer, on the channel region of the substrate; recessing the channel region under the gate structure by removing portions of the channel region below the gate structure at both sides of the gate structure, to form a first recessed channel region; forming a source region, which comprises a first stressor, in the substrate at a side of the gate structure; forming a drain region, which comprises a second stressor, in the substrate at the other side of the gate structure; forming an insulating layer to cover the gate structure and the source and drain regions; removing the dummy gate pattern to expose a portion of the channel region overlapped by the dummy gate pattern; forming a second recessed channel region by recessing the channel region in a downward direction from the top of the substrate; and forming a third stressor in the second recessed channel region.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a cross-sectional view of a semiconductor device fabricated according to an exemplary embodiment;

FIG. 2 is a flowchart illustrating a method of fabricating a semiconductor device according to an exemplary embodiment; and

FIGS. 3 through 16 are cross-sectional views respectively illustrating exemplary operations in the fabrication method of FIG. 2, according to certain embodiments.

### DETAILED DESCRIPTION

Advantages and features described herein and methods of accomplishing the same may be understood more readily by reference to the following detailed description of exemplary embodiments and the accompanying drawings. The present invention may, however, be embodied in many different forms and should not be construed as being limited to the embodiments set forth herein. In the drawings, sizes and relative sizes of components may be exaggerated for clarity. Like numbers refer to like elements throughout. As used herein, the term “and/or” includes any and all combinations of one or more of the associated listed items.

The terminology used herein is for the purpose of describing particular embodiments only and is not intended to be limiting of the disclosed embodiments. As used herein, the singular forms “a”, “an” and “the” are intended to include the plural forms as well, unless the context clearly indicates otherwise. It will be further understood that the terms “comprising,” “including,” and/or “made of,” when used in this specification, specify the presence of stated components, steps, operations, and/or elements, but do not preclude the presence or addition of one or more other components, steps, operations, elements, and/or groups thereof.

It will be understood that, although the terms first, second, third, etc., may be used herein to describe various elements, components and/or sections, these elements, components and/or sections should not be limited by these terms. Unless indicated otherwise, these terms are only used to distinguish one element, component or section from another element, component or section. Thus, a first element, component or section discussed below could be termed a second element, component or section without departing from the teachings of the present invention;

Embodiments are described herein with reference to (plan and) cross-section illustrations that are schematic illustrations of idealized embodiments. As such, variations from the shapes of the illustrations as a result, for example, of manufacturing techniques and/or tolerances, are to be expected. Thus, the disclosed embodiments should not be construed as limited to the particular shapes of regions illustrated herein but are to include deviations in shapes that result, for example, from manufacturing. Thus, the regions illustrated in the figures are schematic in nature and though certain shapes and features are shown, these shapes and features are not intended to limit the scope of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “planar,” or “coplanar,” as used herein when referring to orientation, location, shapes, sizes, amounts, or other measures do not necessarily mean an exactly identical orientation, location, shape, size, amount, or other measure, but are intended to encompass nearly identical orientation, location, shapes, sizes, amounts, or other measures within acceptable variations that may occur, for example, due to manufacturing processes.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

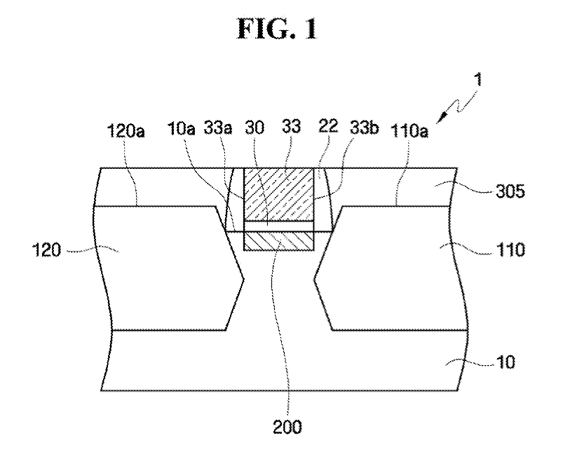

Hereinafter, a method of fabricating a semiconductor device according to exemplary embodiments will be described with reference to FIGS. 1 through 16.

First, a semiconductor device fabricated according to an exemplary embodiment will be described with reference to FIG. 1. FIG. 1 is a cross-sectional view of a semiconductor device 1 fabricated according to an exemplary embodiment. The semiconductor device 1 can include, for example, a semiconductor memory chip, microprocessor chip, or other circuitry that includes transistors on a semiconductor substrate.

Referring to FIG. 1, the semiconductor device 1 fabricated according to the one embodiment may include a semiconductor substrate 10, first semiconductor patterns 110 and 120, a second semiconductor pattern 200, a gate electrode 33, spacers 22, a gate insulating layer 30, and an interlayer insulating layer 305.

The semiconductor substrate 10 may be, for example, a silicon substrate, a silicon-on-insulator (SOI) substrate, a gallium arsenic substrate, or a silicon germanium substrate. However, other semiconductor materials may be used. For example, typical examples of useful semiconductor materials are: Group IV materials, such as Si, C, or Ge, or alloys of these such as SiC or SiGe; Group II-VI compounds (including binary, ternary, and quaternary forms), e.g., compounds formed from Group II materials such as Zn, Mg, Be or Cd and Group VI materials such as Te, Se or S, such as ZnSe, ZnSTe, or ZnMgSTe; and Group III-V compounds (including binary, ternary, and quaternary forms), e.g., compounds formed from Group III materials such as In, Al, or Ga and group V materials such as As, P, Sb or N, such as InP, GaAs, GaN, InAlAs, AlGaN, InAlGaAs, etc.

The semiconductor substrate 10 may be of a first conductivity type or a second conductivity type. For example, the conductivity type of the semiconductor substrate 10 may be a p- or n-type.

The gate insulating layer 30 is disposed on the semiconductor substrate 10. The gate insulating layer 30 insulates an active region formed in the semiconductor substrate 10 from the gate electrode 33. The gate insulating layer 30 may be, for example, a thermal oxide layer or a silicon oxide (SiOx) layer, such as a layer of FOX (Flowable OXide), TOSZ (Tonen SilaZene), USG (Undoped Silicate Glass), BSG (Boro Silicate Glass), PSG (Phospho Silicate Glass), BPSG (BoroPhospho Silicate Glass), PE-TEOS (Plasma Enhanced-Tetra Ethyl Ortho Silicate), FSG (Fluoride Silicate Glass), or HDP (high density plasma).

In one embodiment, the gate electrode 33 is disposed on the gate insulating layer 30. The gate electrode 33 may be made of a conductive material, such as, for example, poly-Si, poly-SiGe, a metal, such as Ta, TaN, TaSiN, TiN, Mo, Ru, Ni or NiSi, or a combination of these materials. The gate electrode 33 may be formed on the semiconductor substrate 10 to extend in a first direction between a first side surface 33a and a second side surface 33b. Accordingly, the gate insulating layer 30 may also extend on the semiconductor substrate 10 in the first direction.

In one embodiment, the spacers 22 may be disposed on both side surfaces of the gate insulating layer 30 and the gate electrode 33. The spacers 22 may include, for example, a nitride film, an oxide film, or another insulating material.

The first semiconductor pattern 110 and 120 are disposed in the semiconductor substrate 10 on both sides of the gate electrode 33 and the spacers 22. Hereinafter, the first semiconductor pattern 110 disposed on a first side of the gate electrode 33 and the spacers 22 will be referred to as a first stressor, and the first semiconductor pattern 120 disposed on the a second, opposite side thereof will be referred to as a second stressor.

The first semiconductor patterns 110 and 120 may extend in the first direction, to extend outward in the first direction from the sides of the gate electrode and the spacers 22. A portion of the first semiconductor patterns 110 and 120 may be located within trenches formed in the semiconductor substrate 10 on both sides of the gate electrode 33 and the spacers 22. In one embodiment, the first semiconductor patterns 110 and 120 may be formed such that a step is created between top surfaces 110a and 120a of the first semiconductor patterns 110 and 120 and a top surface 10a of the semiconductor substrate 10. For example, the top surfaces 110a and 120a of the first semiconductor patterns 110 and 220 may be at a higher level than the top surface 10a of the semiconductor substrate 10. However, this is just one example, and other configurations may be implemented as well.

In a first embodiment, the first stressor 110 and the second stressor 120 (i.e., the first semiconductor patterns 110 and 120) may apply compressive stress to the semiconductor substrate 10. The compressive stress may increase the mobility of holes among carriers of a metal oxide semiconductor (MOS) transistor.

To this end, the first and second stressors 110 and 120 may have different lattice constants from that of the semiconductor substrate 10. More specifically, when the MOS transistor of the semiconductor device 1 is a p-type MOS (PMOS) transistor, the first and second stressors 110 and 120 may be made of a semiconductor material having a greater lattice constant than that of the semiconductor material that forms the semiconductor substrate 10. For example, in one embodiment, when the semiconductor substrate 10 contains Si, the first and second stressors 110 and 120 may contain SiGe or another compound having a greater lattice constant than that of Si. Accordingly, compressive stress may be applied to a channel region under the gate electrode 33, thereby increasing the mobility of the holes of the PMOS transistor.

The first stressor 110 may be a source region of the MOS transistor, and the second stressor 120 may be a drain region of the MOS transistor. Conversely, the first stressor 110 may be the drain region of the MOS transistor, and the second stressor 120 may be the source region of the MOS transistor. In addition, in one embodiment, the first and second stressors 110 and 120 may be doped with a Group 3 element from the periodic table. For example, when the first and second stressors 110 and 120 contain SiGe, SiGe may be doped with B, Ga, or In.

In a second embodiment, the first stressor 110 and the second stressor 120 may apply tensile stress to the semiconductor substrate 10. The tensile stress may increase the mobility of electrons among the carriers of the MOS transistor.

To this end, the first and second stressors 110 and 120 may have different lattice constants from that of the semiconductor substrate 10. More specifically, when the MOS transistor of the semiconductor device 1 is an n-type MOS (NMOS) transistor, the first and second stressors 110 and 120 may be made of a semiconductor material having a smaller lattice constant than that of the semiconductor material that forms the semiconductor substrate 10. For example, in one embodiment when the semiconductor substrate 10 contains Si, the first and second stressors 110 and 120 may contain SiC or another compound having a smaller lattice constant than that of Si. Accordingly, tensile stress may be applied to the channel region under the gate electrode 33, thereby increasing the mobility of the electrons of the NMOS transistor.

The first stressor 110 may be the source region of the MOS transistor, and the second stressor 120 may be the drain region of the MOS transistor. Conversely, the first stressor 110 may be the drain region of the MOS transistor, and the second stressor 120 may be the source region of the MOS transistor. In addition, in one embodiment, the first and second stressors 110 and 120 may be doped with a Group 5 element from the periodic table. For example, when the first and second stressors 110 and 120 contain SiC, SiC may be doped with N, P, or As.

The second semiconductor pattern 200 is formed in the channel region of the semiconductor substrate 10 which is overlapped by the gate electrode 33. Like the first semiconductor patterns 110 and 120, the second semiconductor pattern 200 applies compressive or tensile stress to the semiconductor substrate 10. That is, the second semiconductor pattern 200 functions as a third stressor. Since the second semiconductor pattern 200 overlaps the channel region, it can apply increased stress to the channel region, which, in turn, further increases the mobility of the carriers of the semiconductor device 1.

In a first embodiment, when the second semiconductor pattern 200 applies compressive stress to the semiconductor substrate 10, the mobility of the holes among the carriers of the MOS transistor may increase.

To this end, the second semiconductor pattern 200 may have a different lattice constant from that of the semiconductor substrate 10. More specifically, when the MOS transistor of the semiconductor device 1 is a PMOS transistor, the second semiconductor pattern 200 may be made of a semiconductor material having a greater lattice constant than that of the semiconductor material that forms the semiconductor substrate 10. For example, when the semiconductor substrate 10 contains Si, the second semiconductor pattern 200 may contain SiGe or another compound having a greater lattice constant than that of Si. Accordingly, compressive stress may be applied to the channel region under the gate electrode 33, thereby increasing the mobility of the holes of the PMOS transistor.

In a second embodiment, when the second semiconductor pattern 200 applies tensile stress to the semiconductor substrate 10, the mobility of the electrons among the carriers of the MOS transistor may increase.

To this end, the second semiconductor pattern 200 may have a different lattice constant from that of the semiconductor substrate 10. More specifically, when the MOS transistor of the semiconductor device 1 is an NMOS transistor, the second semiconductor pattern 200 may be made of a semiconductor material having a smaller lattice constant than that of the semiconductor material that forms the semiconductor substrate 10. For example, when the semiconductor substrate 10 contains Si, the second semiconductor pattern 200 may contain SiC or another compound having a smaller lattice constant than that of Si. Accordingly, tensile stress may be applied to the channel region under the gate electrode 33, thereby increasing the mobility of the electrons of the NMOS transistor. As a result of the first through third stressors, a particular stress can be applied to the channel region in at least three directions (i.e., from above and from each side). In addition, although the first through third stressors may be composed of the same compound or material, different materials may be used that apply different amounts of stress on the semiconductor substrate 10.

In one embodiment, an interlayer insulating layer 305 is disposed on the semiconductor substrate 10. The interlayer insulating layer 305 may be made of SiOx such as FOX, TOSZ, USG, BSG, PSG, BPSG, PE-TEOS, FSG, or HDP. The interlayer insulating layer 305 may also be made of other insulating materials, such as, for example, SiNx.

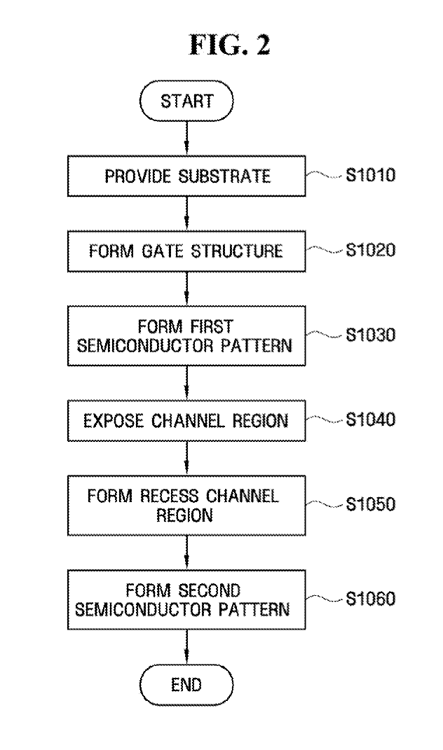

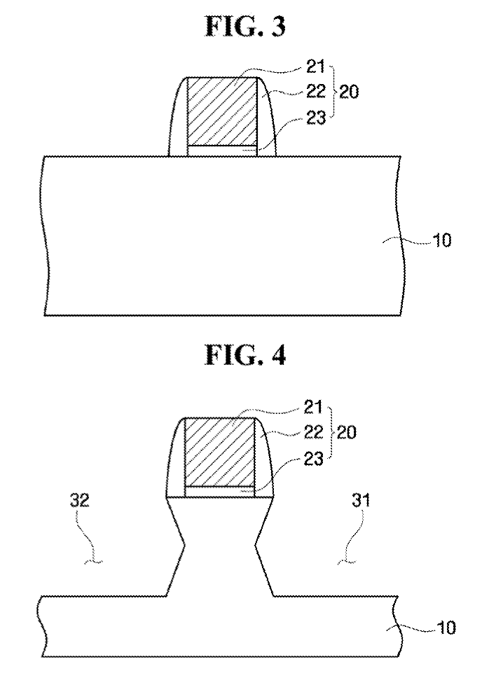

Hereinafter, a method of fabricating a semiconductor device according to an exemplary embodiment will be described with reference to FIGS. 1 through 16. FIG. 2 is a flowchart illustrating a method of fabricating a semiconductor device according to an exemplary embodiment. FIGS. 3 through 16 are cross-sectional views respectively illustrating operations in the fabrication method of FIG. 2.

Referring to FIGS. 2 and 3, a semiconductor substrate 10 is provided (operation S1010). The semiconductor substrate 10 may contain a semiconductor material, e.g., Si.

In one embodiment, a film (not shown) for forming a gate insulating film 23 is formed on the semiconductor substrate 10. The film for forming the gate insulating film 23 may be formed, for example, of SiOx on the whole surface of the semiconductor substrate 10 by chemical vapor deposition (CVD). Then, a film (not shown) for forming a dummy gate pattern 21 is formed, for example, of p-Si on the film for forming the gate insulating film 23 by CVD.

Next, the film for forming the gate insulating film 23 and the film for forming the dummy gate pattern 21 are etched to form the gate insulating film 23 and the dummy gate pattern 21, respectively.

In one embodiment, a film (not shown) for forming spacers 22 is then formed to cover the gate insulating film 23 and the dummy gate pattern 21. The film for forming the spacers 22 may be formed of, e.g., SiOx by CVD. The film for forming the spacers 22 is etched back to form the spacers 22 on both side surfaces of the gate insulating film 23 and the dummy gate pattern 21. As a result, a gate structure 20 is formed on the semiconductor substrate 10 (operation S1020).

Referring to FIG. 4, the semiconductor substrate 10 is then etched to form first and second trenches 31 and 32. The first and second trenches 31 and 32 are formed by etching the semiconductor substrate 10 on both sides of the gate structure 20. The etching of the semiconductor substrate 10 may be achieved, for example, by a dry-etching or wet-etching process. The first and second trenches 31 and 32 may be formed inward toward a center of the gate structure 20 in a direction parallel to the first direction described above (e.g., in a direction between the side surfaces of the gate structure 20). The first and second trenches 31 and 32 may be recessed from a top surface of the semiconductor substrate 10 toward a bottom surface thereof, to form a recessed channel, such that the semiconductor substrate 10 is thinner in the first direction at the middle of the substrate than at the top and/or bottom of the substrate.

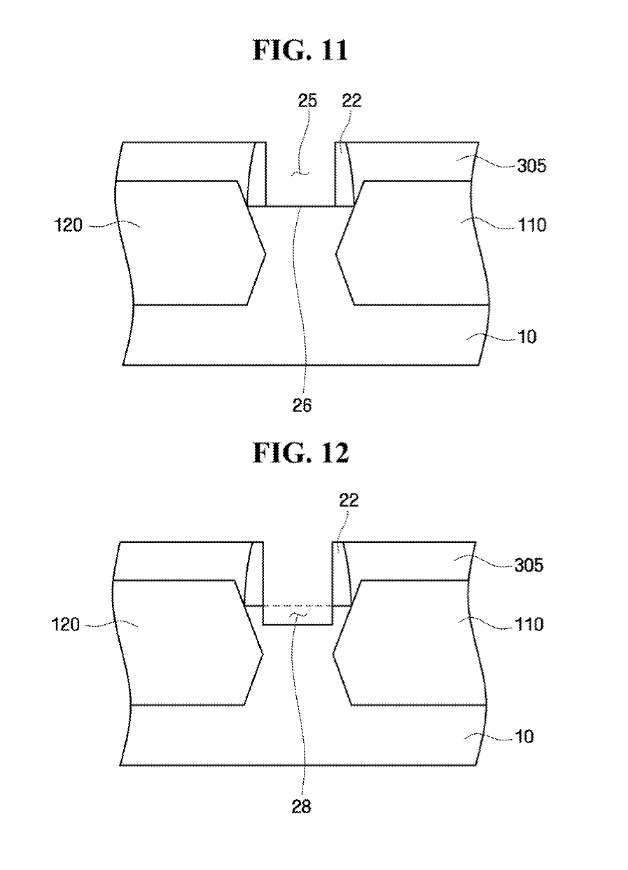

A first stressor 110 (see FIG. 1) and a second stressor 120 (see FIG. 1) are respectively formed in the first trench 31 and the second trench 32 in a subsequent process. To maximize the compressive or tensile stress applied to the semiconductor substrate 10 by the first and second stressors 110 and 120, part of a sidewall of each of the first and second trenches 31 and 32 may be recessed toward a channel region 26 (see FIG. 11). Accordingly, a cross-sectional shape of each of the first and second trenches 31 and 32, taken in a direction from the top surface to the bottom surface of the semiconductor substrate 10, may be a sigma (Σ) shape. However, the cross-sectional shape of each of the first and second trenches 31 and 32 is not limited to the sigma shape, and can be in other shapes that have a similar effect (e.g., sides of the first and second trenches 31 and 32 can have curved shapes). As such, the first and second trenches 31 and 32 can have any cross-sectional shape that maximizes the compressive or tensile stress applied to the semiconductor substrate 10 by the first and second stressors 110 and 120.

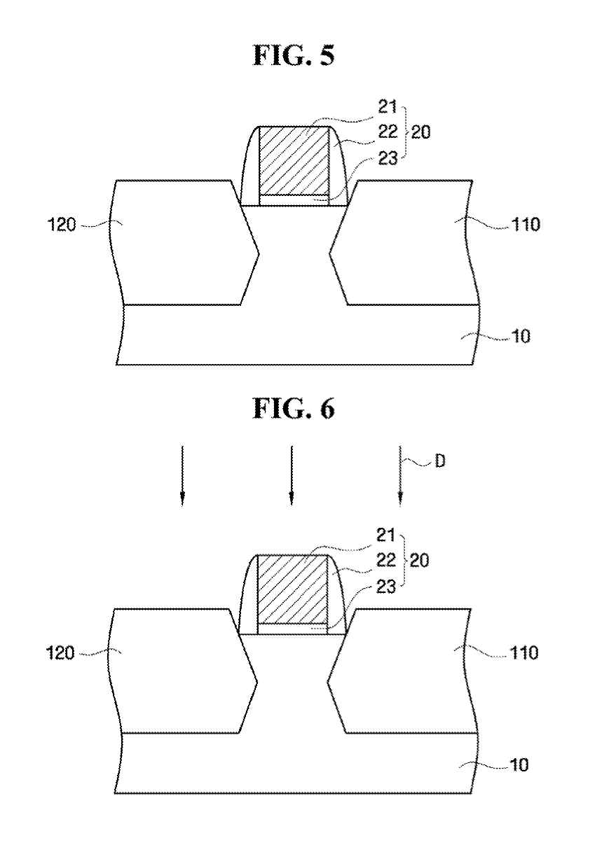

Referring to FIGS. 3 and 5, first semiconductor patterns 110 and 120 are formed in the first and second trenches 31 and 32 (operation S1030). That is, the first stressor 110 may be formed in the first trench 31, and the second stressor 120 may be formed in the second trench 32.

In one embodiment, the first and second stressors 110 and 120 may be formed by epitaxially growing a semiconductor material in the first and second trenches 31 and 32. The first and second stressors 110 and 120 may extend in the first direction, outward from the channel region 26.

In a first embodiment, when a semiconductor device 1 is a PMOS transistor, the first and second stressors 110 and 120 may be made of a semiconductor material having a greater lattice constant than that of the semiconductor material that forms the semiconductor substrate 10. For example, in an embodiment where the semiconductor substrate 10 is made of Si, the first and second stressors 110 and 120 may be formed by epitaxially growing SiGe or another compound having a greater lattice constant than that of Si. In addition, the epitaxially grown material can include impurities. For example, B-containing SiGe may be epitaxially grown using Si₂H₂Cl₂, B₂H₆, HCl or H₂ at 600 to 800° C. That is, an epitaxial layer of SiGe that contains a Group 3 element from the periodic table may be formed. Thus, the first and second stressors 110 and 120 may function as source and drain regions. In this case, an ion doping process for injecting impurities into the first and second stressors 110 and 120 may not be necessary.

In a second embodiment, when the semiconductor device 1 is an NMOS transistor, it may be made of a semiconductor material having a smaller lattice constant than that of the semiconductor material that forms the semiconductor substrate 10. For example, in an embodiment where the semiconductor substrate 10 is made of Si, the first and second stressors 110 and 120 may be formed by epitaxially growing SiC or another compound having a smaller lattice constant than that of Si. In addition, the epitaxially grown material can include impurities. For example, P-containing SiC may be epitaxially grown using SiH₄, C₃H₆, PH₃ or HCl at 600 to 800° C. That is, an epitaxial layer of SiC that contains a Group 5 element from the periodic table may be formed. Thus, the first and second stressors 110 and 120 may function as the source and drain regions. In this case, an ion doping process for injecting impurities into the first and second stressors 110 and 120 may not be necessary.

Referring to FIG. 6, when the first and second stressors 110 and 120 are an epitaxial layer that does not contain Group 3 or 5 impurities, an additional process D of doping impurities into the first and second stressors 110 and 12 may be performed to enable the first and second stressors 110 and 120 to function as the source and drain regions. However, as described above, the impurity doping process D can be omitted in some cases.

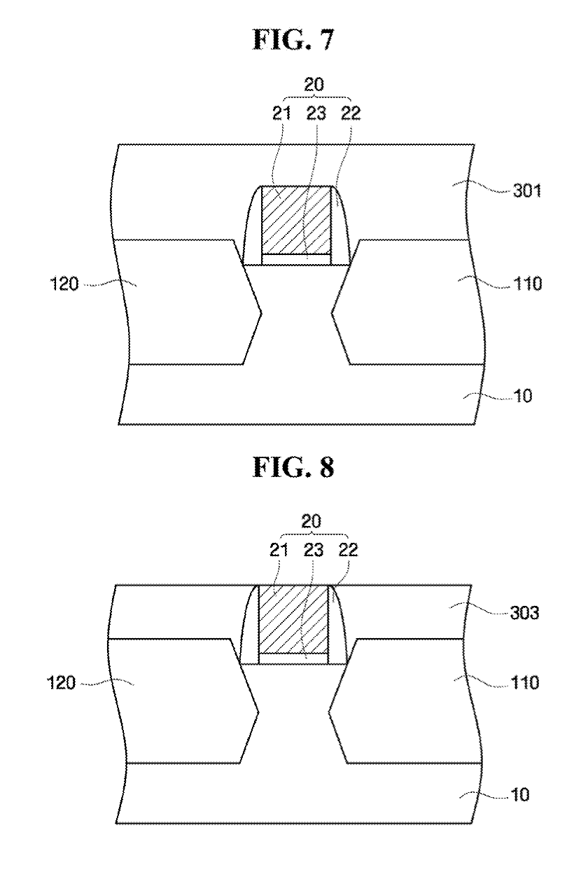

Referring to FIG. 7, an insulating layer 301 is formed on the gate structure 20 and the first and second stressors 110 and 120. In one embodiment, the insulating layer 301 is formed, for example, of SiOx on the whole surface of the semiconductor substrate 10 by CVD. Accordingly, the gate structure 20 and the first and second stressors 110 and 120 are covered with the insulating layer 301.

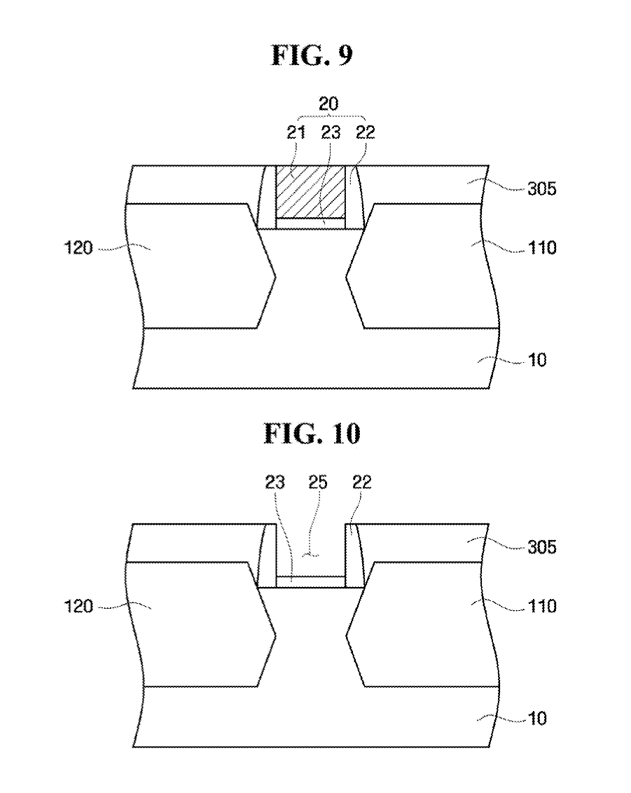

Referring to FIGS. 8 and 9, the insulating layer 301 is planarized to expose a top surface of the gate structure 20. More specifically, in one embodiment, the insulating layer 301 is planarized by chemical mechanical polishing (CMP) to expose a top surface of the dummy gate pattern 21 of the gate structure 20.

Then, upper parts of the insulating layer 303 and the gate structure 20 are partially and simultaneously planarized. Accordingly, upper parts of the dummy gate pattern 21 and the spacers 22 of the gate structure 20 may be partially etched, and may have top surfaces that are coplanar.

Referring to FIGS. 2, 10 and 11, in one embodiment, the dummy gate pattern 21 of the gate structure 20 is then completely removed. Accordingly, the gate insulating film 23 of the gate structure 20 may be exposed. In addition, a space 25 for forming a gate electrode 33 (see FIG. 1) is formed in the gate structure 20. The dummy gate pattern 21 may be removed, for example, by a wet-etching or dry-etching process.

The gate insulating film 23 of the gate structure 20 is then completely removed, for example, by a wet-etching or dry-etching process. Accordingly, the channel region 26 of the semiconductor substrate 10 which is overlapped by the dummy gate pattern 21 may be exposed (operation S1040).

Referring to FIGS. 2 and 12, in one embodiment, the channel region 26 is recessed from the top surface of the semiconductor substrate 10 toward the bottom surface thereof, thereby forming a recessed channel region 28 (operation S1050). The recessed channel region 28 may be formed, for example, by wet-etching or dry-etching the channel region 26 of the semiconductor substrate 10 in a direction from the top surface of the semiconductor substrate 10 toward the bottom surface thereof. A cross-sectional shape of the recessed channel region 28, taken in the direction from the top surface of the semiconductor substrate 10 toward the bottom surface thereof, may be rectangular as shown in FIG. 12. However, the cross-sectional shape of the recess channel region 28 is not limited to the square shape. The recessed channel region 28 can have any cross-sectional shape that maximizes the compressive or tensile stress applied to the semiconductor substrate 10 by a second semiconductor pattern 200 (see FIG. 1) that is to be formed in a subsequent process, and may include both the recess formed from the top surface of the semiconductor substrate 10 toward the bottom surface thereof, and the recesses caused by trenches 31 and 32 described in FIG. 4.

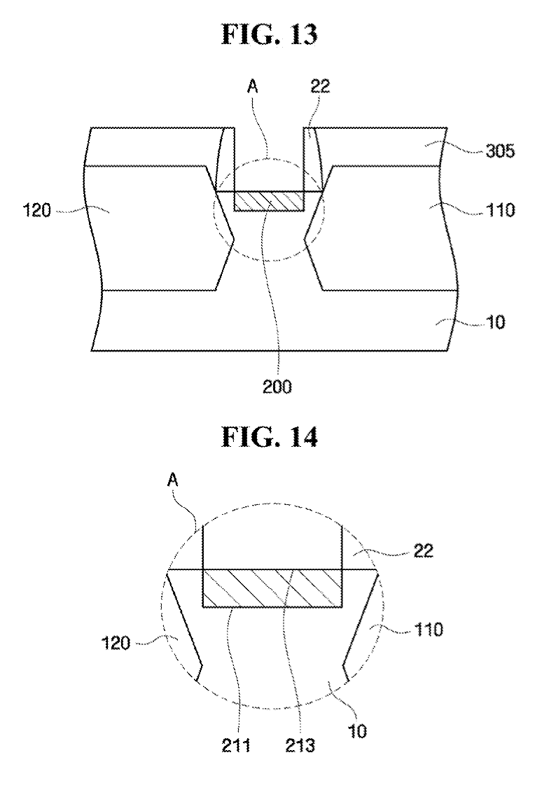

Referring to FIGS. 2 and 13, the second semiconductor pattern 200 is formed in the recessed channel region 28 (operation S1060).

The second semiconductor pattern 200 may be formed, for example, by epitaxially growing a semiconductor material in the recessed channel region 28. In one embodiment, when the semiconductor device 1 is a PMOS transistor, the second semiconductor pattern 200 may be made of a semiconductor material having a greater lattice constant than that of the semiconductor material that forms the semiconductor substrate 10. For example, when the semiconductor substrate 10 is made of Si, the second semiconductor pattern 200 may be formed by epitaxially growing SiGe or another compound having a greater lattice constant than that of Si.

In another embodiment, when the semiconductor device 1 is an NMOS transistor, the second semiconductor pattern 200 may be made of a semiconductor material having a smaller lattice constant than that of the semiconductor material that forms the semiconductor substrate 10. For example, when the semiconductor substrate 10 is made of Si, the second semiconductor pattern 200 may be formed by epitaxially growing SiC or another compound having a smaller lattice constant than that of Si.

In addition, in one embodiment, the second semiconductor pattern 200 may apply different magnitudes of compressive or tensile stress to the semiconductor substrate 10 in the recessed channel region 28, which will be described in detail below.

In a first example, it is assumed that the second semiconductor pattern 200 applies compressive stress. Referring to FIG. 14, the second semiconductor pattern 200 may be formed to have different concentrations of Ge, for example, in the recessed channel region 28. That is, the lattice constant of the second semiconductor pattern 200 may depend on the concentration of Ge. When a concentration gradient of Ge is formed in the recessed channel region 28, the lattice constant of the second semiconductor pattern 200 may vary according to the concentration gradient of Ge. The variation in the lattice constant of the second semiconductor pattern 200 may result in a corresponding variation in the compressive stress applied to the semiconductor substrate 10 by the second semiconductor pattern 200. For example, when the second semiconductor pattern 200 is formed such that the concentration of Ge is reduced from a lower part 211 of the second semiconductor pattern 200 toward an upper part 213 thereof, the lower part 211 of the second semiconductor pattern 200 which is adjacent to the channel region 26 may apply a relatively greater compressive stress to the semiconductor substrate 10 than the upper part 213 which is adjacent to the top surface of the semiconductor substrate 10. This may further increase the mobility of holes in the channel region 26.

As a second example, it is assumed that the second semiconductor pattern 200 applies tensile stress. Referring to FIG. 14, the second semiconductor pattern 200 may be formed to have different concentrations of C, for example, in the recessed channel region 28. That is, the lattice constant of the second semiconductor pattern 200 may depend on the concentration of C. When a concentration gradient of C is formed in the recessed channel region 28, the lattice constant of the second semiconductor pattern 200 may vary according to the concentration gradient of C. The variation in the lattice constant of the second semiconductor pattern 200 may result in a corresponding variation in the tensile stress applied to the semiconductor substrate 10 by the second semiconductor pattern 200. For example, when the second semiconductor pattern 200 is formed such that the concentration of C is reduced from the lower part 211 of the second semiconductor pattern 200 toward the upper part 213 thereof, the lower part 211 of the second semiconductor pattern 200 which is adjacent to the channel region 26 may apply a relatively greater tensile stress to the semiconductor substrate 10 than the upper part 213 which is adjacent to the top surface of the semiconductor substrate 10. This may further increase the mobility of electrons in the channel region 26.

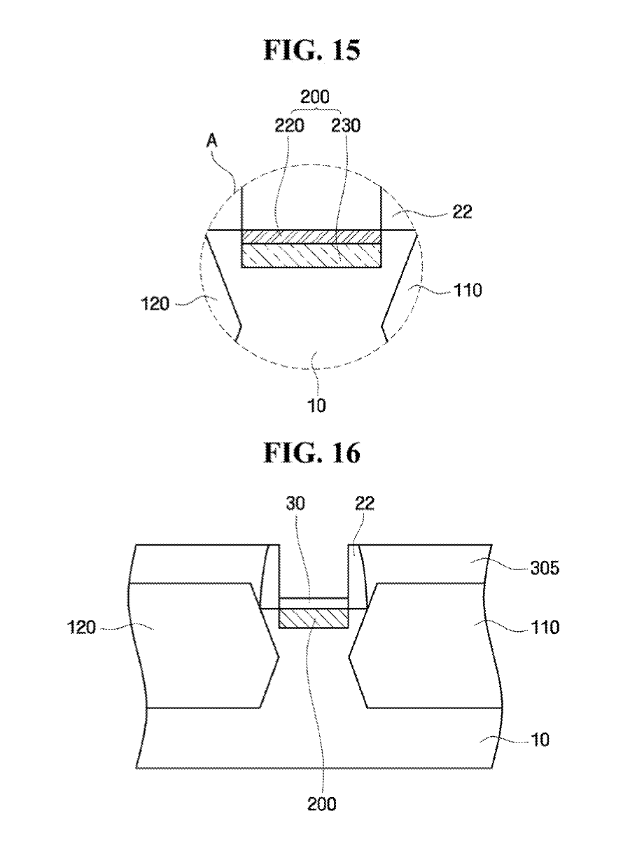

Referring to FIG. 15, the second semiconductor pattern 200 may be formed to include a capping layer 220 and a stress applying layer 230. The stress applying layer 230 applies compressive or tensile stress to the semiconductor substrate 10. To apply compressive stress, the stress applying layer 230 may contain, e.g., Ge. To apply tensile stress, the stress applying layer 230 may contain, e.g., C.

The capping layer 220 is disposed on the stress applying layer 230. The capping layer 220 prevents the second semiconductor pattern 200 from being damaged when a gate insulating layer 30 is formed in a subsequent process. That is, the capping layer 220 can prevent the stress applying layer 230 from being damaged by a heat treatment process that may be performed in the formation of the gate insulating layer 30.

In one embodiment, the capping layer 220 may be made of the same material as the semiconductor material that forms the semiconductor substrate 10. For example, when the semiconductor substrate 10 contains Si, the capping layer 220 may also contain Si. That is, unlike the stress applying layer 230, the capping layer 220 may not contain Ge or C which produces compressive or tensile stress.

In one embodiment, the boundary between the capping layer 220 and the stress applying layer 230 may not be clear. More specifically, the concentration of Ge or C in the second semiconductor pattern 200 may vary according to position, and may not change from a first concentration to a second, substantially different concentration. As such, the concentration may change gradually from a first concentration to a second concentration, and may not change abruptly from the first concentration to the second concentration at the boundary. For example, the concentration of Ge or C may be reduced in a direction from the lower part 211 of the second semiconductor pattern 200 which is adjacent to the channel region 26 toward the top surface of the semiconductor substrate 10. Here, if the concentration of Ge or C is gradually reduced in the above direction, the upper part 213 of the second semiconductor pattern 200 which is adjacent to the top surface of the semiconductor substrate 10 may have a region in which the concentration of Ge or C is substantially zero (i.e., such that the substrate effectively has the same properties as if the concentration were zero). This region may be defined as the capping layer 220, and a region in which the concentration of Ge or C substantially exceeds zero may be defined as the stress applying layer 230.

Unlike the above case, the boundary between the stress applying layer 230 and the capping layer 220 may be clear and abrupt. However, even in this case, the concentration of Ge or C in the stress applying layer 230 may vary according to position, before an abrupt change to the capping layer, which has substantially zero concentration of Ge or C.

Referring to FIG. 16, a film (not shown) for forming the gate insulating layer 30 is formed on the second semiconductor pattern 200 and the interlayer insulating layer 305. The film for forming the gate insulating layer 30 may be formed of, e.g., SiOx on the whole surface of the second semiconductor pattern 200 and the interlayer insulating layer 305 by CVD. Next, the film for forming the gate insulating layer 30 is removed, excluding its portion in the space 25 (see FIG. 10) from which the dummy gate pattern 21 has been removed. As a result, the gate insulating layer 30 is formed in the space 25.

Referring to FIG. 1, a material for forming the gate electrode 33 is then deposited on the whole surface of the semiconductor substrate 10 to fill the space 25. Then, a damascene process is performed to form the gate electrode 33 in the space 25.

While the present disclosure has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A method of fabricating a semiconductor device, the method comprising:
providing a substrate having a channel region;
forming a gate structure, which comprises a dummy gate pattern, on the substrate;
forming first and second trenches by recessing the substrate on both sides of the gate structure, respectively;
forming a first semiconductor pattern in the first and second trenches;
removing the dummy gate pattern to expose a portion of the channel region;
forming a recessed channel region by recessing the portion of the channel region; and
forming a second semiconductor pattern in the recessed region.

2. The method of claim 1, wherein the first and second semiconductor patterns comprise a semiconductor material that applies compressive or tensile stress to the substrate.

3. The method of claim 2, wherein the second semiconductor pattern applies different magnitudes of compressive stress to the substrate at different portions of the second semiconductor pattern.

4. The method of claim 3, wherein the second semiconductor pattern comprises a compressive stress applying layer made of Si—Ge.

5. The method of claim 4, wherein the concentration of Ge varies in the compressive stress applying layer.

6. The method of claim 5, wherein the concentration of Ge is reduced from a lower part of the compressive stress applying layer toward an upper part thereof.

7. The method of claim 4, wherein the second semiconductor pattern further comprises a capping layer, wherein the capping layer is disposed on the compressive stress applying layer.

8. The method of claim 2, wherein the first semiconductor pattern comprises Si—Ge doped with a Group 3 element from a periodic table.

9. The method of claim 1, wherein a portion of the first and second trenches are overlapped by the gate structure, and
forming the first semiconductor pattern further comprises epitaxially growing the first semiconductor pattern in the first and second trenches.

10. The method of claim 9, wherein forming the second semiconductor pattern further comprises epitaxially growing the second semiconductor pattern in the recessed region.

11. A method of fabricating a semiconductor device, the method comprising:
providing a substrate having a channel region;
forming a gate structure, which comprises a dummy gate pattern and a gate insulating layer, on the channel region of the substrate;
recessing the channel region under the gate structure by removing portions of the channel region below the gate structure at both sides of the gate structure, to form a first recessed channel region;
forming a source region, which comprises a first stressor, in the substrate at a side of the gate structure;
forming a drain region, which comprises a second stressor, in the substrate at the other side of the gate structure;
forming an insulating layer to cover the gate structure and the source and drain regions;
removing the dummy gate pattern to expose a portion of the channel region overlapped by the dummy gate pattern;
forming a second recessed channel region by recessing the channel region in a downward direction from the top of the substrate; and
forming a third stressor in the second recessed channel region.

12. The method of claim 11, wherein the substrate include a first lattice structure, and the first, second, and third stressors include a second lattice structure different from the first lattice structure, the second lattice structure comprising a semiconductor material that applies compressive or tensile stress to the first lattice structure.

13. The method of claim 12, wherein the third stressor applies different magnitudes of compressive stress to the substrate at different portions of the third stressor.

14. The method of claim 13, further comprising forming the third stressor by epitaxially growing the third stressor on the second recessed channel region.

15. The method of claim 14, wherein the third stressor comprises a compressive stress applying layer made of Si—Ge, and the concentration of Ge varies in the compressive stress applying layer.
